(19) United States
(12) Patent Application Publication
(10) Pub. No.: US 2024/0153748 A1
(43) Pub. Date: May 9, 2024

(54) CONTROL METHOD OF SUBSTRATE PROCESSING APPARATUS AND SUBSTRATE PROCESSING APPARATUS

(71) Applicant: Tokyo Electron Limited, Tokyo (JP)

(72) Inventor: Morihito INAGAKI, Yamanashi (JP)

(21) Appl. No.: 18/383,673

(22) Filed: Oct. 25, 2023

(30) Foreign Application Priority Data
Nov. 7, 2022 (JP) 2022-178447

(51) Int. Cl. H01J 37/32

(52) U.S. Cl. CPC H01J 37/32715; H01J 37/32761; H01J 2237/332

(57) ABSTRACT

A method of controlling a substrate processing apparatus includes providing a substrate processing apparatus that includes a processing container, and a rotary table provided in the processing container and having a plurality of substrate placing portions in a circumferential direction on a top surface thereof; forming films on substrates on the substrate placing portions according to a process recipe by rotating the rotary table; unloading the substrates on the substrate placing portions from the processing container after the forming; and rotating the rotary table until before the unloading after the forming.

### CROSS-REFERENCE TO RELATED APPLICATIONS

The present application is based on and claims priority from Japanese Patent Application No. 2022-178447, filed on Nov. 7, 2022, with the Japan Patent Office, the disclosure of which is incorporated herein in its entirety by reference.

### TECHNICAL FIELD

The present disclosure relates to a substrate processing apparatus and a control method of the substrate processing apparatus.

### BACKGROUND

Japanese Patent Laid-Open Publication No. 2019-121674, for example, suggests a method of setting the time when the uniformity between surfaces is the best as a film formation time, during the formation of a silicon-containing film on each substrate. The film formation process is executed over a predetermined film formation time set by a predetermined cycle time and a predetermined number of cycles while a plurality of substrates is placed on a rotary table within a processing chamber, and the rotary table is rotated.

### SUMMARY

According to an aspect of the present disclosure, provided is a method of controlling a substrate processing apparatus. The substrate processing apparatus includes: a processing container; and a rotary table provided within the processing container and having a plurality of substrate placing portions in a circumferential direction on a top surface thereof. The control method includes the steps of: forming films on substrates on the substrate placing portions according to a process recipe by rotating the rotary table; unloading the substrates on the substrate placing portions from the processing container after the forming; and rotating the rotary table until before the unloading after the forming.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view of a substrate processing apparatus according to one embodiment.

FIG. 2 is a perspective view illustrating a schematic internal configuration of the substrate processing apparatus of FIG. 1.

FIG. 3 is a plan view illustrating a schematic internal configuration of the substrate processing apparatus of FIG. 1.

FIGS. 4A and 4B are longitudinal sectional views illustrating an example of a supply region and a separation region in the substrate processing apparatus of FIG. 1.

FIG. 5 is a partially cutaway perspective view of the substrate processing apparatus of FIG. 1.

FIG. 6 is a view illustrating an example of the status of the substrate processing apparatus and the status of the rotary table according to one embodiment.

FIG. 7 is a flowchart illustrating an example of the control method of the substrate processing apparatus according to one embodiment.

FIG. 8 is a view illustrating an example of the control method of FIG. 7.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to drawings. In the drawings, the same components will be denoted by the same reference numerals, and redundant explanations thereof may be omitted in some cases.

[Substrate Processing Apparatus]

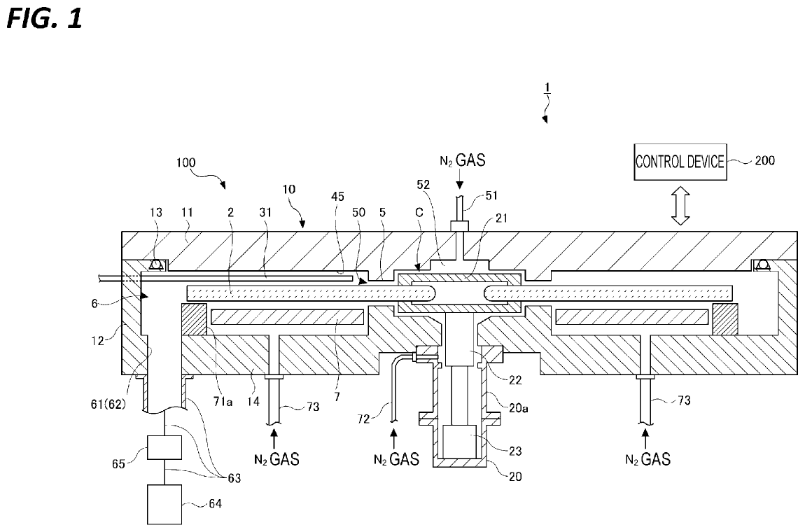

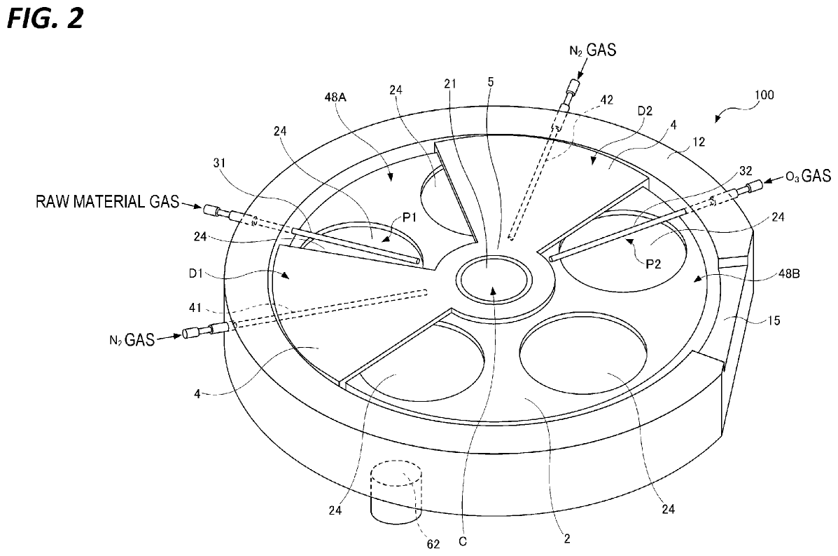

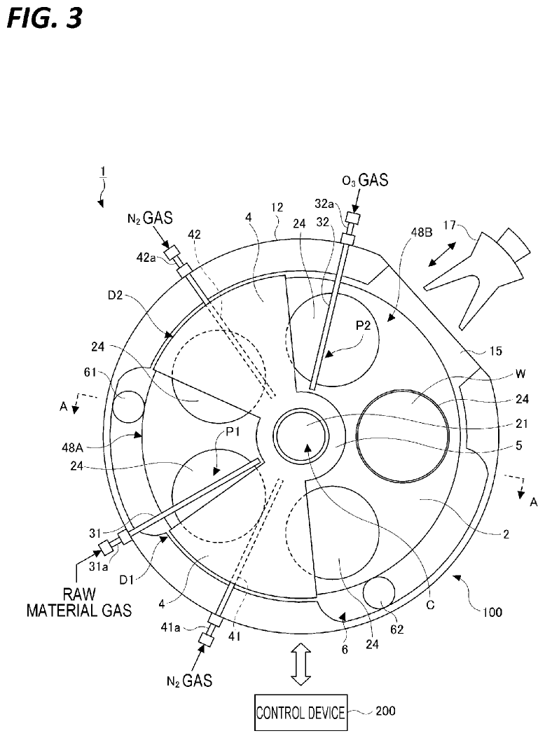

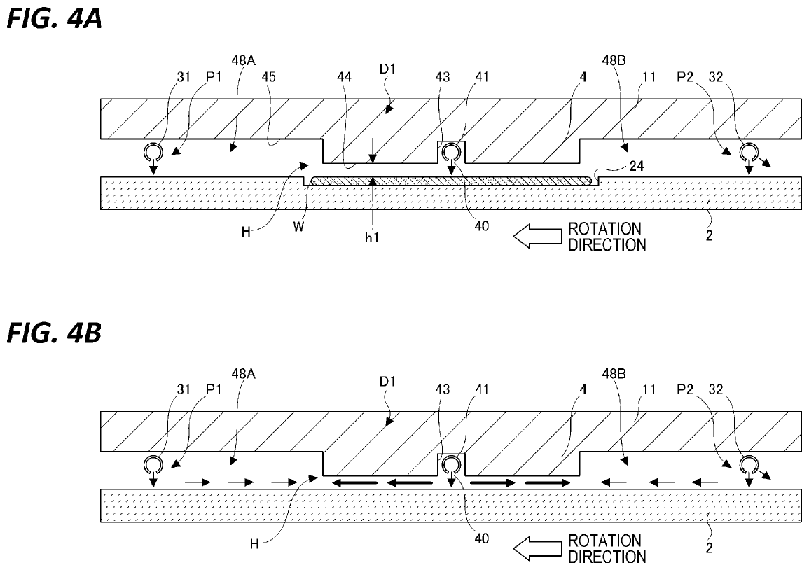

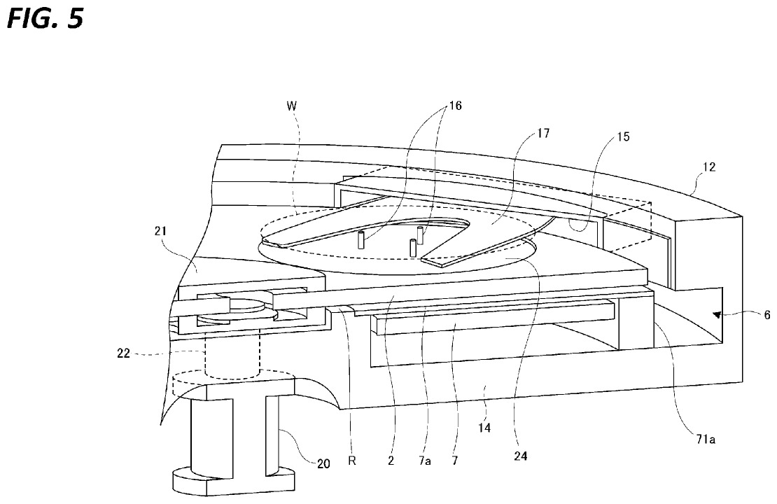

Although the control method of a substrate processing apparatus according to an embodiment of the present disclosure may be applied to various substrate processing apparatuses equipped with a rotary table, hereinafter, descriptions will be made on a substrate processing apparatus according to one embodiment, to which the control method of the substrate processing apparatus according to the embodiment of the present disclosure may be suitably applied. FIG. 1 is a schematic cross-sectional view of a substrate processing apparatus to which the control method of a substrate processing apparatus according to one embodiment is applied. FIG. 2 is a perspective view illustrating a schematic internal configuration of the substrate processing apparatus of FIG. 1. FIG. 3 is a plan view illustrating a schematic internal configuration of the substrate processing apparatus of FIG. 1. FIGS. 4A and 4B are longitudinal sectional views illustrating an example of a supply region and a separation region in the substrate processing apparatus of FIG. 1. FIG. 5 is a partially cutaway perspective view of the substrate processing apparatus of FIG. 1.

As illustrated in FIG. 1 (a cross-sectional view taken along the A-A line in FIG. 3) to FIG. 3, a substrate processing apparatus 1 to which the control method of the substrate processing apparatus according to one embodiment is applied includes a flat vacuum processing container 10 having an approximately circular planar shape, and a rotary table 2 having a rotation center at the center of the processing container 10. Furthermore, the substrate processing apparatus 1 includes a control device 200 that controls the overall operation of the apparatus. The processing container 10 defines a processing chamber 100 for accommodating a substrate W as an example of a wafer and for forming a film on the surface of the substrate W. The processing container 10 is constituted by a container body 12, and a ceiling plate 11 separable from the container body 12. The ceiling plate 11 is attached to the container body 12 via, for example a sealing member 13 such as an O-ring, and thereby the processing container 10 is airtightly sealed. The ceiling plate 11 and the container body 12 may be made of, for example, aluminum (Al). Also, the rotary table 2 may be made of, for example, quartz.

As illustrated in FIG. 1 and FIG. 5, the rotary table 2 is disk-shaped, has a circular opening at the center thereof, and is held by a cylindrical core 21 sandwiched from above and below around the opening. The core 21 is fixed to the upper end of a rotating shaft 22 extending in the vertical direction. The rotating shaft 22 passes through a bottom 14 of the container body 12, and its lower end is attached to a driving unit 23 that rotates the rotating shaft 22 around the vertical axis. Through this configuration, the rotary table 2 may rotate around its central axis as the rotation center. The rotating shaft 22 and the driving unit 23 are housed within a tubular case body 20 with an open top surface. The case body 20 is airtightly attached to the lower surface of the bottom 14 of the processing container 10 via a flange 20a provided on the upper surface thereof, so that the internal atmosphere of the case body 20 is isolated from the external atmosphere.

As illustrated in FIG. 2 and FIG. 3, a plurality of (e.g., five in the illustrated example) recesses 24 on which the substrates W are placed is formed at equal angular intervals on the top surface of the rotary table 2. The recess 24 is circular in plan view. However, in FIG. 3, only one substrate W is illustrated. The plurality of recesses 24 is an example of a plurality of substrate placing portions provided on the rotary table 2 in the circumferential direction.

As illustrated in FIG. 2 to FIGS. 4A and 4B, two convex portions 4 spaced apart from each other are provided along the rotation direction of the rotary table 2. In FIGS. 2 and 3, in order to facilitate the explanation on the inside of the processing container 10, the illustration of the ceiling plate 11 is omitted. That is, FIGS. 2 and 3 illustrate the inside of the processing container 10 in a state where the ceiling plate 11 is removed while the convex portions 4 are left in the processing container 10. As illustrated in FIGS. 4A and 4B, the convex portions 4 are provided on the lower surface of the ceiling plate 11. As can be seen from FIG. 3, the convex portion 4 has an approximately fan-like planar shape. The apex of the approximately fan-like shape is located substantially at the center of the processing container 10, and the arc of the approximately fan-like shape is located along the inner peripheral wall of the container body 12. Further, as illustrated in FIG. 4A, the convex portion 4 is disposed such that its lower surface 44 is located at a height hi from the rotary table 2 or the substrate W placed in the recess 24.

As illustrated in FIG. 3 and FIGS. 4A and 4B, the convex portion 4 has a groove 43 that extends in the radial direction so as to divide the convex portion 4 into two parts, and a separation gas nozzle 41 (42) is accommodated in the groove 43. In the present embodiment, the groove 43 is formed to divide the convex portion 4 into two equal parts, but for example, the groove 43 may be formed such that the convex portion 4 on the upstream side in the rotation direction of the rotary table 2 is wider. As illustrated in FIG. 3, the separation gas nozzle 41 (42) is introduced from the peripheral wall of the container body 12 into the processing container 10, and is supported with a gas introduction port 41a (42a) (the base end of the separation gas nozzle 41 (42)) attached to the outer peripheral wall of the container body 12.

The separation gas nozzle 41 (42) is connected to a gas supply source (not illustrated) of a separation gas. As for the separation gas, for example, an inert gas such as a nitrogen (N₂) gas or a rare gas may be applied, but the type of the gas is not particularly limited as long as it does not affect film formation. In the present embodiment, N₂ gas is used as the separation gas. The separation gas nozzle 41 (42) has discharge holes 40 (see, e.g., FIGS. 4A and 4B) for discharging N₂ gas toward the surface of the rotary table 2. The discharge holes 40 are disposed at predetermined intervals in the length direction.

Through the above configuration, a separation region D1 that defines a separation space H is provided by the separation gas nozzle 41 and the corresponding convex portion 4. Similarly, a separation region D2 that defines a separation space H is provided by the separation gas nozzle 42 and the corresponding convex portion 4. On the downstream side of the separation region D1 in the rotation direction of the rotary table 2, a first region 48A (a first supply region) is formed, which is generally surrounded by the separation regions D1 and D2, the rotary table 2, a lower surface 45 of the ceiling plate 11 (hereinafter, a ceiling surface 45), and the inner peripheral wall of the container body 12. Furthermore, on the upstream side of the separation region D1 in the rotation direction of the rotary table 2, a second region 48B (e.g., a second supply region) is formed, which is generally surrounded by the separation regions D1 and D2, the rotary table 2, the ceiling surface 45, and the inner peripheral wall of the container body 12. When N₂ gas is discharged from the separation gas nozzles 41 and 42 in the separation regions D1 and D2, the pressure of the separation spaces H becomes relatively high, and the N₂ gas flows from the separation spaces H toward the first region 48A and the second region 48B. That is, due to the convex portions 4 in the separation regions D1 and D2, N₂ gas provided from the separation gas nozzles 41 and 42 is guided to the first region 48A and the second region 48B.

As illustrated in FIG. 2 and FIG. 3, in the first region 48A, a raw material gas nozzle 31 is introduced from the peripheral wall of the container body 12 in the radial direction of the rotary table 2. In the second region 48B, a reactive gas nozzle 32 that supplies an oxidizing gas such as ozone gas is introduced from the peripheral wall of the container body 12 in the radial direction of the rotary table. Like the separation gas nozzles 41 and 42, the raw material gas nozzle 31 and the reactive gas nozzle 32 are supported with gas introduction ports 31a and 32a (base ends) attached to the outer peripheral wall of the container body 12. In addition to ozone, oxygen may be applied as the oxidizing gas. In the present embodiment, a silicon oxide film (SiO₂) is formed as a silicon-containing film on the substrate W, but in an embodiment in which a silicon nitride film (SiN) is formed as the silicon-containing film, a nitrogen-containing gas such as NH₃ is supplied from the reactive gas nozzle 32.

The raw material gas nozzle 31 is connected to a raw material gas supply source (not illustrated), and the reactive gas nozzle 32 is connected to an ozone gas supply source (not illustrated). Although various gases may be used as the raw material gas, in the present embodiment, a silicon-containing gas is used. Specifically, aminosilane gases such as DIPAS (diisopropylaminosilane) gas, 3DMAS (trisdimethylaminosilane) gas, and BTBAS (bistertiarybutylaminosilane) gas may be exemplified. Hereinafter, a mode in which DIPAS gas is applied as the raw material gas will be described. In the following description, regarding the region below the raw material gas nozzle 31, a region where the DIPAS gas is adsorbed on the substrate W may be referred to as a processing region P1 in some cases. Regarding the region below the reactive gas nozzle 32, a region for causing O₃ gas to react with (oxidize) the DIPAS gas adsorbed on the substrate W may be referred to as a processing region P2 in some cases.

A plasma processing region may be provided above the rotary table 2 between the reactive gas nozzle 32 and the separation gas nozzle 41. The plasma processing region is equipped with an inductivity coupled plasma (ICP) generator, and the plasma generator is connected to a high-frequency power source capable of generating high frequency waves having a frequency of, for example, 13.56 MHz. A gas introduction port (not illustrated) is attached to the outer peripheral wall of the container body 12, and a reactive gas nozzle (not illustrated) supported by the gas introduction port is introduced in the radial direction of the rotary table 2 similarly to, for example, the raw material gas nozzle 31. The reactive gas nozzle is connected to an argon gas supply source (not illustrated) filled with argon (Ar) gas, an oxygen gas supply source (not illustrated) filled with oxygen (O₂) gas, and a hydrogen gas supply source (not illustrated) filled with hydrogen (H₂) gas. Ar gas, O₂ gas, and H₂ gas whose flow rates are controlled by corresponding flow rate controllers are supplied at a predetermined flow rate ratio (a mixing ratio) from the argon gas supply source, the oxygen gas supply source, and the hydrogen gas supply source to the plasma processing region. The reactive gas nozzle has a plurality of discharge holes formed at predetermined intervals along the length direction of the reactive gas nozzle, and the above-described mixed gas of Ar, O₂, and H₂ is discharged from the discharge holes. When high frequency power is supplied to the plasma generator, an electromagnetic field is generated, and an electric field component in the electromagnetic field is propagated into the plasma processing region. Due to the electric field component, plasma is generated from the mixed gas of Ar, O₂, and H₂ supplied to the plasma processing region through the reactive gas nozzle, and the plasma of the mixed gas of Ar, O₂, and H₂ performs uniform modification processing of the silicon-containing film.

With reference to FIG. 1 to FIG. 3 again, an annular protrusion 5 is provided on the ceiling surface 45 of the ceiling plate 11 so as to surround the core 21. The protrusion 5 faces the rotary table 2 in an area outside the core 21. In the present embodiment, the height from the rotary table 2 on the lower surface of a space 50 is slightly lower than the height hi of the space H. This is because the rotational vibration is small near the center of the rotary table 2.

With reference to FIG. 1, a separation gas supply pipe 51 is connected to the center of the ceiling plate 11 of the processing container 10. Through this configuration, N₂ gas is supplied to a space 52 between the ceiling plate 11 and the core 21. Due to the N₂ gas supplied to the space 52, the narrow space 50 between the protrusion 5 and the rotary table 2 may be maintained at a higher pressure than the first region 48A and the second region 48B. Thus, the DIPAS gas discharged from the raw material gas nozzle 31 in the first region 48A may not pass through the high-pressure space 50 and reach the second region 48B. The O₃ gas discharged from the reactive gas nozzle 32 in the second region 48B may not pass through the high-pressure space 50 and reach the first region 48A. Therefore, both gases are separated by the space 50, and are hardly mixed in the gas phase within the processing container 10. That is, in the substrate processing apparatus of the present embodiment, in order to separate the DIPAS gas and the O₃ gas from each other, a central region C is provided, which is defined by the rotation center of the rotary table 2 and the processing container 10 and is maintained at a higher pressure than the first region 48A and the second region 48B.

As illustrated in FIG. 3, in the first region 48A and the second region 48B, the inner peripheral wall of the container body 12 is recessed outwards, and at these places, exhaust regions 6 are formed. At the bottoms of the exhaust regions 6, as illustrated in FIG. 1 and FIG. 3, for example, exhaust ports 61 and 62 are provided. Each of the exhaust ports 61 and 62 is connected to, for example, a common vacuum pump 64 which is a vacuum exhaust device via an exhaust pipe 63. Through this configuration, gases in the first region 48A and the second region 48B are mainly exhausted, and as described above, the pressure in the first region 48A and the second region 48B may be lower than the pressure in the separation spaces H of the separation regions D1 and D2. In FIG. 3, although the exhaust region 6 is provided at a location where the inner peripheral wall of the container body 12 is recessed outwards, this configuration is not essential. Various configurations, in which the exhaust ports 61 and 62 are provided at the bottom, are applicable.

As illustrated in FIG. 3, the exhaust port 61 corresponding to the first region 48A is located below the raw material gas nozzle 31 on the outside of the rotary table 2 (the exhaust region 6). Accordingly, the DIPAS gas discharged from the discharge holes of the raw material gas nozzle 31 may flow along the top surface of the rotary table 2, toward the exhaust port 61 in the length direction of the raw material gas nozzle 31.

Referring back to FIG. 1, a pressure regulator 65 is provided in the exhaust pipe 63, which adjusts the pressure within the processing container 10. A plurality of pressure regulators 65 may be provided for the corresponding exhaust ports 61 and 62. The exhaust ports 61 and 62, without being limited to the bottom of the exhaust region 6 (the bottom 14 of the processing container 10), may be provided in the peripheral wall of the container body 12 of the processing container. The exhaust ports 61 and 62 may be provided on the ceiling plate 11 in the exhaust regions 6. Meanwhile, when the exhaust ports 61 and 62 are provided in the ceiling plate 11, since the gas within the processing container 10 flows upward, there is a risk that particles within the processing container 10 may be rolled up, and the substrate W may be contaminated. For this reason, it is desirable that the exhaust ports 61 and 62 are provided at the bottom as illustrated in the drawings, or are provided at the peripheral wall of the container body 12. When the exhaust ports 61 and 62 are provided at the bottom, the exhaust pipe 63, the pressure regulator 65, and the vacuum pump 64 may be provided below the processing container 10. Thus, this is advantageous in terms of footprint reduction of the substrate processing apparatus 1.

As illustrated in FIG. 1 and FIG. 5, an annular heater unit 7, as a heating unit, is provided in the space between the rotary table 2 and the bottom 14 of the container body 12, and thereby the substrate W placed on the rotary table 2 is heated to a predetermined temperature. A block member 71a is provided below the rotary table 2 and near the outer periphery so as to surround the heater unit 7, and thus, the space where the heater unit 7 is placed is separated from the area outside the heater unit 7. A slight gap is formed between the top surface of the block member 71a and the bottom surface of the rotary table 2 in order to prevent a gas from flowing inside due to the block member 71a. In an area where the heater unit 7 is accommodated, in order to perform purging of this area, a plurality of purge gas supply pipes 73 is connected at predetermined angular intervals through the bottom of the container body 12. Above the heater unit 7, a protection plate 7a that protects the heater unit 7 is supported by the block member 71a, and a raised portion R (see, e.g., FIG. 5). Accordingly, even when the DIPAS gas or the O₃ gas temporarily flows into the space where the heater unit 7 is provided, the heater unit 7 may be protected from these gases. The protection plate 7a is preferably made of, for example, quartz.

As illustrated in FIG. 5, the bottom 14 has the raised portion R inside the annular heater unit 7. The top surface of the raised portion R is close to the rotary table 2 and the core 21, while small gaps are left between the top surface of the raised portion R and the back surface of the rotary table 2, and between the side surface of the raised portion R and the side surface of the core 21. The bottom 14 has a center hole through which the rotating shaft 22 passes. The inner diameter of the center hole is slightly larger than the diameter of the rotating shaft 22, thereby leaving a gap that communicates with the case body 20 via the flange 20a. A purge gas supply pipe 72 is connected to the upper portion of the flange 20a.

As illustrated in FIG. 1 and FIG. 5, N₂ gas flows from the purge gas supply pipe 72 to the space below the rotary table 2 through the gap between the rotating shaft 22 and the center hole of the bottom 14, the gap between the core 21 and the raised portion R of the bottom 14, and the gap between the raised portion R of the bottom 14 and the back surface of the rotary table 2. Also, N₂ gas flows from the purge gas supply pipes 73 to the space below the heater unit 7. Then, these N₂ gases flow into the exhaust port 61 through the gap between the block member 71a and the back surface of the rotary table 2. The N₂ gas flowing in this manner acts as a separation gas that prevents the DIPAS gas (or the O₃ gas) from circulating in the space below the rotary table 2 and being mixed with the O₃ gas) (the DIPAS gas).

As illustrated in FIG. 2, FIG. 3, and FIG. 5, a transport port 15 is formed in the peripheral wall of the container body 12. The substrate W is transported into the processing container 10 or is transported out of the processing container 10 through the transport port 15 by a transport arm 17. A gate valve (not illustrated) is provided in the transport port 15, and thereby the transport port 15 is opened/closed. Three through holes (not illustrated) are formed in the bottom surface of the recess 24. Through these through holes, three lift pins 16 (see, e.g., FIG. 5) may be moved up and down. The lift pins 16 support the back surface of the substrate W, raise and lower the substrate W, and transfer the substrate W from/to the transport arm 17.

As illustrated in FIG. 1 and FIG. 3, the control device 200 controls the overall operation of the substrate processing apparatus 1. The control device 200 includes a process controller constituted by, for example, a computer, a user interface, and a memory device. The user interface includes, for example, a display that displays the operation status of the substrate processing apparatus, and a keyboard or a touch panel which allows the operator of the substrate processing apparatus to select a process recipe, or the process manager to change parameters of the process recipe.

The control device 200 also performs a control for executing a control method of the substrate processing apparatus 1 to be described below. The memory device stores, for example, control programs that cause the process controller to perform various processes, process recipes, and parameters in the various processes. Some of these programs include a group of steps through which, for example, the control method of the substrate processing apparatus 1 to be described below is performed. The control programs or the process recipes are read and executed by the process controller according to instructions from the user interface. Also, these programs may be stored in a computer-readable storage medium, and may be installed in the memory device via a corresponding input/output device (not illustrated). The computer-readable storage medium may be, for example a hard disk, a CD, a CD-R/RW, a DVD-R/RW, a flexible disc, or a semiconductor memory. Also, the programs may be downloaded to the memory device via a communication line.

[Status of Substrate Processing Apparatus and Rotation Status of Rotary Table]

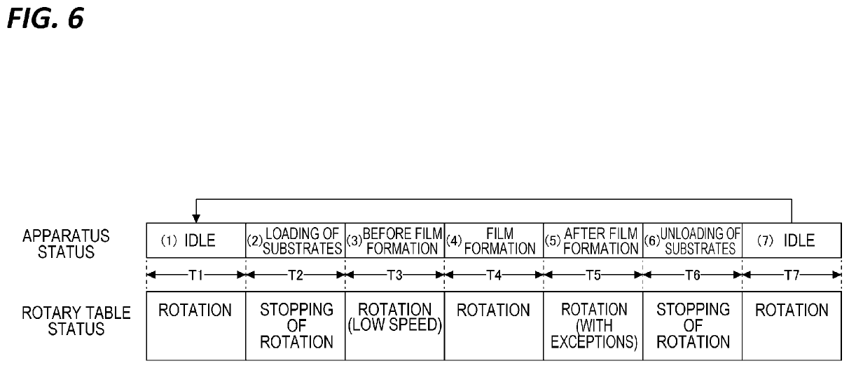

Next, descriptions will be made on the correspondence between the status of the substrate processing apparatus 1 and the status of the rotary table 2 according to one embodiment, with reference to FIG. 6. FIG. 6 is a view illustrating an example of the status of the substrate processing apparatus 1 and the status of the rotary table 2 according to one embodiment. The upper part of FIG. 6 illustrates the status of the substrate processing apparatus 1, and the lower part illustrates the status of the rotary table 2 corresponding to the apparatus status.

As illustrated in the upper part of FIG. 6, the status of the substrate processing apparatus 1 changes in the order of process (1) of idling, process (2) of loading of substrates, process (3) of before film formation, process (4) of film formation, process (5) of after film formation, process (6) of unloading of substrates, and process (7) of idling. In process (4) of the film formation, films are formed at once on substrates W placed on the recesses 24. Similarly, in the next film formation, the status of the substrate processing apparatus 1 changes in the order of processes (1) to (7), and films are formed at once on the next substrates W placed on the recesses 24.

The symbols T1, T2, T3, T4, T5, T6, and T7 are set as times for the process (1) of idling, process (2) of loading of substrates, process (3) of before film formation, process (4) of film formation, process (5) of after film formation, process (6) of unloading of substrates, and process (7) of idling, respectively. During the time T1 for process (1), the time T3 for process (3), the time T5 for process (5), and the time T7 for process (7), a control is performed to adjust the condition of the processing chamber 100.

As illustrated in the lower part of FIG. 6, the control device 200 rotates the rotary table 2 during the time T1 for process (1) of the idle state. During the time T1, a purge gas may be introduced from the plurality of purge gas supply pipes 73.

After the time T1 has elapsed, during the time T2 for process (2) of the loading of substrates, the control device 200 stops the rotation of the rotary table 2, and loads substrates W from the transport port 15. The control device 200 stops the rotation of the rotary table 2 at the timing when a substrate loading instruction is received from a host computer or a higher-level computer (both not illustrated) connectable to the control device 200. Meanwhile, after the time T1 for process (1) has elapsed, the rotation of the rotary table 2 may be automatically stopped. In loading of a plurality of substrates W, the recesses 24 of the rotary table 2 are sequentially disposed in front of the transport port 15, and the substrates W are placed on the recesses 24.

After the time T2 has elapsed, the control device 200 rotates the rotary table 2 during the time T3 before film formation of process (3). Here, for example, the substrate W may be checked for a warpage. In this case, the control device 200 rotates the rotary table 2 at a low speed (e.g., 5 rpm: 5 rotations per min). Meanwhile, the rotational speed is an example, and the control device 200 fixedly or variably controls the rotational speed of the rotary table 2 according to preset parameters.

After the time T3 has elapsed, the control device 200 rotates the rotary table 2 during the time T4 for process (4) of the film formation. Here, the control device 200 controls the process of forming films on the substrates W on the recesses 24 according to a process recipe. The control device 200 rotates the rotary table 2 at a rotational speed set in the process recipe (e.g., 20 rpm: 20 rotations per min), supplies a raw material gas (e.g., DIPAS) from the raw material gas nozzle 31, and supplies a reactive gas (e.g., O₃) from the reactive gas nozzle 32. Also, N₂ gas is supplied from the separation gas nozzles 41 and 42. Accordingly, a silicon oxide film is formed, as an example of a silicon-containing film, on the substrate W placed on the recess 24 of the rotary table 2.

After the time T4 has elapsed, the control device 200 maintains the rotation of the rotary table 2 during the time T5 after film formation of process (5). The maintaining of the rotation is a state in which the rotation is not stopped, and it does not matter whether the rotational speed is high or low. That is, during the time T5 after the film formation, the rotational speed of the rotary table 2 may be the same as or may be higher or lower than the rotational speed of the rotary table 2 during the film formation.

The heater unit 7 is provided in the space between the rotary table 2 and the bottom 14 of the container body 12, so that the substrate W placed on the rotary table 2 is heated to a predetermined temperature during process (4) of the film formation.

Therefore, when the rotation of the rotary table 2 is stopped immediately after the film formation, when the time T5 until before the unloading of the substrate W becomes longer, the rotary table 2 is heated under the influence of the heater unit 7 below the rotary table 2, and the substrate is heated by radiant heat of the rotary table 2. As a result, in some cases, during the time T5 after film formation of process (5), the influence of the temperature on the substrates W may be increased, and the substrates W may be warped.

For example, when the set temperature of the heater unit 7 is, for example, 600° C. during process (4) of the film formation, the temperature of the substrate W is lowered to about 300° C. during the time T5 after film formation of process (5), and then the substrate W is unloaded in process (6). Therefore, when the rotation of the rotary table 2 is stopped during the time T5 after film formation of process (5), due to the heater unit 7, the substrate W is affected by the temperature, and the substrate W is likely to warp.

In the meantime, in the control method of the substrate processing apparatus 1 according to the present embodiment, during the time T5 after film formation of process (5), the rotation of the rotary table 2 is maintained. Accordingly, it is possible to improve the uniformity of heat in the plurality of substrates W, so that the influence of the temperature on each substrate W may be suppressed and minimized, and the warpage of the substrate W may be suppressed.

Furthermore, by rotating the rotary table 2, it is possible to more quickly lower the temperature of the substrate W to a temperature at which the substrate W may be unloaded. In particular, during the time T5 after film formation of process (5), in some cases, a purge gas may be supplied from the plurality of purge gas supply pipes 73. In this case, by rotating the rotary table 2, it is possible to reduce a deviation in the supply of the purge gas, and to further improve the uniformity of heat in the substrates W. Thus, the influence of the temperature on the substrates W may be more effectively reduced.

Further, as illustrated in FIG. 4A, when there is a height difference between the ceiling surfaces 44 and 45, below the ceiling surface 44 lower than the ceiling surface 45, the substrate W is easily affected by heat (e.g., the influence of the temperature). Therefore, when the rotation of the rotary table 2 is stopped during the time T5 after film formation of process (5), the substrate W located below the ceiling surface 44 is affected by more heat than the substrate W located below the ceiling surface 45.

From the above, in the control method of the substrate processing apparatus 1 according to the present embodiment, the rotation of the rotary table 2 is maintained even during the time T5 after film formation of process (5). Accordingly, it is possible to improve the uniformity of heat in the plurality of substrates W on the rotary table 2, so that the influence of the temperature on the substrates W may be minimized, and the warpage of the substrates W may be suppressed.

As an example, during the time T5 after film formation of process (5), as for the rotational speed of the rotary table 2, the rotational speed for the process may be maintained. Meanwhile, as long as the rotational speed is such that the substrate W does not jump out of the substrate placing portion (e.g., the recess 24), the rotation may be performed at a speed that is either higher or lower than the rotational speed during the process. During the time T5 after the film formation, the rotational speed of the rotary table 2 may be either fixed or variable, and is preferably controlled to be a rotational speed effective for thermal uniformity or warpage of the substrates W. For example, it is desirable that the control device 200 fixedly or variably controls the rotational speed of the rotary table 2 so as to reduce the influence of the temperature on the substrates W on the substrate placing portions (e.g., the recesses 24).

After the time T5 has elapsed, during the time T6 for process (6) of the unloading of substrates, the control device 200 stops the rotation of the rotary table 2, and unloads the substrates W from the transport port 15. The control device 200 may stop the rotation of the rotary table 2 at the timing when a substrate unloading instruction is received from a host computer or a higher-level computer, or may automatically stop the rotation of the rotary table 2 after the time T5 for process (5) has elapsed. In unloading of the plurality of substrates W, the recesses 24 of the rotary table 2 are sequentially disposed in front of the transport port 15, and the substrates W are lifted by the lift pins 16 from the recesses 24 and unloaded from the transport port 15 by the transport arm 17 (see, e.g., FIG. 5).

After the time T6 has elapsed, the control device 200 rotates the rotary table 2 during the time T7 for process (7) of the idle state. When there are next substrates W to be processed, the control device 200 returns the process to process (1) of the idle state, and waits for an instruction to load the next substrates W. During the time T7 and the time T1, a purge gas may be introduced from the plurality of purge gas supply pipes 73.

Among all the processes (1) to (7), in process (4) of the film formation process, the rotational speed and the rotation direction of the rotary table 2 are set for each of steps of the process recipe, and in each process other than process (4), the rotational speed and the rotation direction are set in a parameter setting area of the memory device. In each of the processes (1) to (7), the control device 200 controls the rotational speed and the rotation direction of the rotary table 2 on the basis of each setting value which is set in the parameter setting area or set for each of steps of the process recipe.

In the method of setting the rotational speed and the rotation direction of the rotary table 2 for process (4) of the film formation, the rotational speed and the rotation direction may be set for each lot, and the rotational speed and the rotation direction may be set for substrates corresponding to the number of sheets to be processed at one time.

In process (4) of the film formation, when the stopping of the rotation of the rotary table 2 is set in the final step of the process recipe (that is, the rotational speed is 0), the control device 200 continues to stop the rotation of the rotary table 2 even during the time T5 after film formation of process (5). For example, in a case where there is no problem with the influence of the temperature on the substrates W even when the rotation of the rotary table 2 is stopped after film formation, for example, in a case where the temperature set for process (4) of film formation is relatively low, the rotation is stopped during the time T5 for process (5) (e.g., in the case of exception for process (5) in FIG. 6). As a result, immediately after the time T5 has elapsed, process (6) of unloading of substrates may be performed, and the throughput may be improved.

[Control Method of Substrate Processing Apparatus]

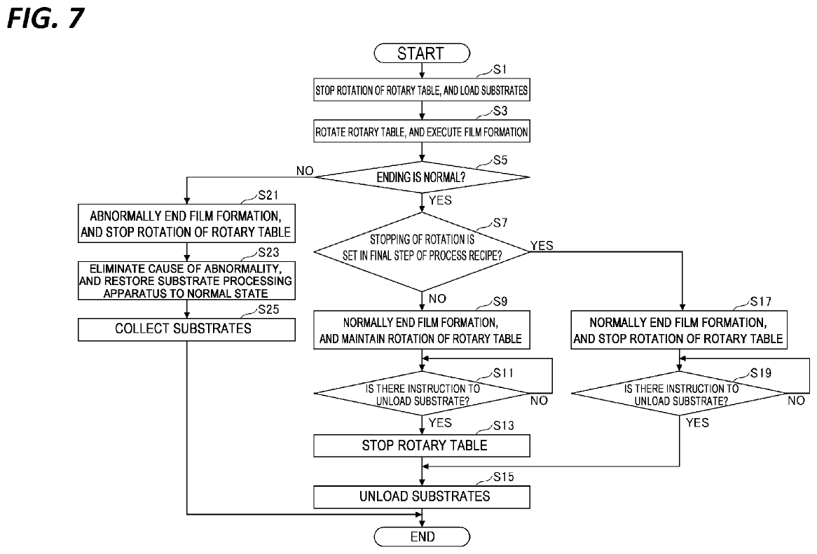

Next, descriptions will be made on the control method of the substrate processing apparatus 1 according to one embodiment, with reference to FIG. 7. FIG. 7 is a flowchart illustrating an example of the control method of the substrate processing apparatus 1 according to one embodiment. The control method of the substrate processing apparatus 1 according to the present embodiment is controlled by the control device 200.

In a state where the substrate processing apparatus 1 rotates the rotary table 2 during process (1) of the idle state of FIG. 6, the control device 200 starts the present control method upon receiving a substrate loading instruction from a host computer or a higher-level computer.

In step S1, the control device 200 stops the rotation of the rotary table 2, loads substrates W from the transport port 15, and places the substrates W on the recesses 24 of the rotary table 2 (e.g., process (2) in FIG. 6). A maximum of five substrates W may be placed on the rotary table 2.

Next, in step S3, the control device 200 rotates the rotary table 2 (e.g., process (3) in FIG. 6), checks, for example, a warpage of the substrates W, and then executes film formation on the substrates W (e.g., process (4) in FIG. 6).

Next, in step S5, the control device 200 determines whether the film formation process has ended normally. When the control device 200 determines that the film formation process has ended normally, the process proceeds to step S7. When it is determined that the film formation process has ended abnormally, the process proceeds to step S21 to be described below. In step S7, the control device 200 determines whether the stopping of the rotation is set in a final step of a process recipe.

When it is determined that the stopping of the rotation is not set in the final step of the process recipe in step S7, the control device 200 normally ends the film formation process in step S9, and thereafter maintains the rotation of the rotary table 2 (e.g., process (5) in FIG. 6).

Next, in step S11, the control device 200 determines whether there is an instruction to unload the substrate. The control device 200 waits until there is an instruction to unload the substrate. When the instruction is received, the process proceeds to step S13. The control device 200 stops the rotation of the rotary table 2, and then unloads the substrates W in step S15 (e.g., process (6) in FIG. 6), and ends this process. The substrate processing apparatus 1 is placed in an idle state (e.g., process (7) in FIG. 6) until a loading instruction for next substrates to be processed is received.

When it is determined that the stopping of the rotation is set in the final step of the process recipe in step S7, the control device 200 normally ends the film formation process in step S17, and then stops the rotation of the rotary table 2 (e.g., exception of process (5) in FIG. 6).

Next, in step S19, the control device 200 determines whether there is an instruction to unload the substrate. The control device 200 waits until there is an instruction to unload the substrate. When the instruction is received, the process proceeds to step S15. The control device 200 unloads the substrates W (e.g., process (6) in FIG. 6), and ends this process. The substrate processing apparatus 1 is placed in an idle state (e.g., process (7) in FIG. 6) until a loading instruction for next substrates to be processed is received.

Meanwhile, when it is determined that the film formation process has ended abnormally in step S5, the control device 200 abnormally ends the film formation process in step S21, and stops the rotation of the rotary table 2. Next, in step S23, the control device 200 performs a control to eliminate the cause of the abnormality in the film formation process, and to restore the substrate processing apparatus 1 to a normal state. Next, in step S25, the control device 200 collects the substrates W from the substrate processing apparatus 1, and ends this process. The substrate processing apparatus 1 is placed in an idle state until a loading instruction for next substrates to be processed is received.

[Unloading of Substrates]

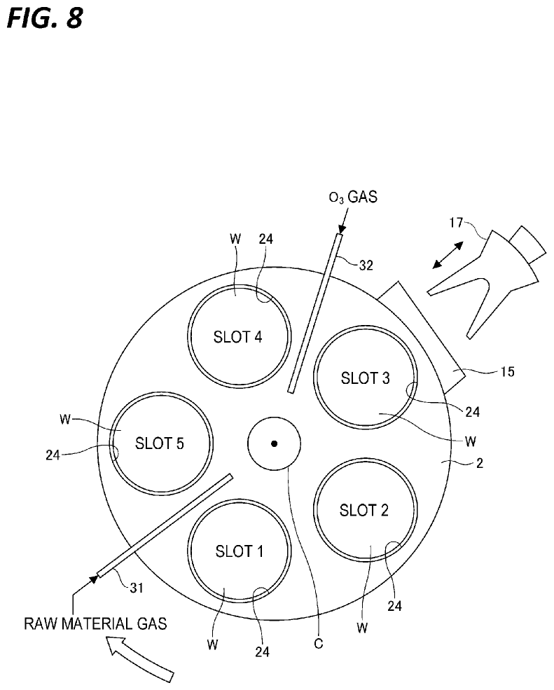

In unloading of the substrates, the substrates W are sequentially unloaded from the rotary table 2. For example, as illustrated in FIG. 8, the five recesses 24 provided in the circumferential direction of the rotary table 2 are set as slot 1 to slot 5. When five substrates W are placed on the recesses 24 of slot 1 to slot 5, the longer the waiting time until each substrate W is unloaded, the more heat affects the substrate.

In order to reduce such an influence of heat (e.g., the influence of the temperature) on the substrates W, the rotation of the rotary table 2 is maintained and continued even after the film formation process, and then the rotation of the rotary table is stopped when a substrate unloading instruction indicating the timing when unloading may be actually performed is received. Accordingly, the substrate W, which waits for a long time until unloading, may be suppressed from being affected by heat or from being warped.

In unloading of the substrate W, it is necessary to stop the rotation of the rotary table 2 such that the slot position of the substrate W reaches the position of the transport port 15 (e.g., origin position) where the substrate W may be transferred to the transport arm 17. A substrate unloading instruction is issued for each substrate W. Therefore, even when the rotation of the rotary table 2 is stopped after the film formation process and before the unloading of the substrates, when a substrate unloading instruction is issued, the substrate W for which the instruction is issued has to be rotated so as to be moved to the origin position.

In the control method of the substrate processing apparatus 1 according to the present embodiment, the rotation of the rotary table 2 is maintained, with exceptions, until before the unloading of the substrates after the film formation process. For this reason, when a substrate unloading instruction is issued, the substrate W at the slot position to be unloaded may be moved to the origin position, and the rotation of the rotary table 2 may be stopped. For example, in the example of FIG. 8, the substrate W at the slot 3 to be unloaded is moved to the origin position, and the rotation of the rotary table 2 is stopped. This eliminates the need for acceleration (e.g., re-rotation) of the rotary table 2, which is required for unloading the substrate when the rotation of the rotary table 2 is stopped after the film formation process. Thus, it is possible to move the rotary table 2 to the origin position and to stop the rotation at the same time by performing only a deceleration operation. This may reduce a change in the status of the rotational movement of the rotary table 2, so that particles may be reduced.

For example, in step S11 of FIG. 7, when the control device 200 determines whether the substrate unloading instruction has been received, if the plurality of substrates W is placed on the plurality of substrate placing portions (e.g., the recesses 24), the substrate unloading instruction is received for each of the substrates W.

The control device 200 unloads a substrate W for which the substrate unloading instruction has been received first, prior to a substrate W for which the instruction has been received later. That is, the control device 200 decelerates the rotary table 2 and stops the rotation such that the position (e.g., slot position) of the substrate placing portion (e.g., the recess 24) of the substrate W for which the instruction has been received first is controlled to be the position of the transport port 15 (e.g., origin position). Accordingly, the stopping of the rotation of the rotary table 2, and the position control for unloading the substrate W may be performed at the same time. Thus, it is possible to quickly unload the substrates while reducing the influence of the temperature on the substrates W, and suppressing the warpage of the substrates W. Furthermore, particles may be reduced. Also, the substrate unloading instructions may be received such that the substrates W are unloaded one by one from the substrate W that was firstly loaded into the substrate processing apparatus 1, and thus the influence of the temperature on the substrates W may be further reduced.

As described above, according to the control method of the substrate processing apparatus 1 and the substrate processing apparatus 1 according to the present embodiment, in the substrate processing apparatus having the rotary table, it is possible to reduce the influence of the temperature on substrates after films are formed on the substrates on the rotary table.

According to one aspect, in the substrate processing apparatus having the rotary table, it is possible to reduce the influence of the temperature on substrates after films are formed on the substrates on the rotary table.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A control method comprising:
providing a substrate processing apparatus including
a processing container; and
a rotary table provided in the processing container and having a plurality of substrate placing portions in a circumferential direction on a top surface thereof;
forming films on substrates on the substrate placing portions according to a process recipe by rotating the rotary table;
unloading the substrates on the substrate placing portions from the processing container after the forming; and
rotating the rotary table until before the unloading after the forming.

2. The control method according to claim 1, wherein when stopping of rotation of the rotary table is set in a final step of the forming in the process recipe, the rotation of the rotary table is stopped after the forming.

3. The control method according to claim 1, wherein in the rotating, a rotational speed is variably controlled to reduce an influence of temperature on the substrates on the substrate placing portions.

4. The control method according to claim 1, wherein in the unloading, in order to sequentially unload the substrates on the substrate placing portions, rotation of the rotary table is decelerated and stopped such that a position of one of the substrate placing portions is aligned with a position of a transfer port.

5. The control method according to claim 4, wherein in the unloading, an unloading instruction is received for each of the substrates on the substrate placing portions, and the rotation of the rotary table is decelerated and stopped such that a position of the substrate placing portion of a substrate for which the unloading instruction is received first is controlled to be a position corresponding to the transport port, so that the substrate for which the unloading instruction is received first is unloaded prior to a substrate for which the unloading instruction is received later.

6. A substrate processing apparatus comprising:
a processing container;
a rotary table provided in the processing container, and having a plurality of substrate placing portions in a circumferential direction on a top surface thereof; and
a controller,
wherein the controller controls processing including:
forming films on substrates on the substrate placing portions according to a process recipe by rotating the rotary table,
unloading the substrates on the substrate placing portions from the processing container after the forming, and
rotating the rotary table until before the unloading after the forming.
